(19) United States
(12) Patent Application Publication
(10) Pub. No.: US 2023/0377810 A1
(43) Pub. Date: Nov. 23, 2023

(54) METHOD OF MAKING AN ELECTRODE HAVING MULTI-WALLED CARBON NANOTUBES

(71) Applicant: KING FAISAL UNIVERSITY, Al-Ahsa (SA)

(72) Inventors: FAHEEM AHMED, AL-AHSA (SA); NAGIH SHALAN, AL-AHSA (SA); SHALENDRA KUMAR, AL-AHSA (SA); ABDULLAH ALJAAFARI, AL-AHSA (SA); ADIL ALSHOAIBI, AL-AHSA (SA); NISHAT ARSHI, AL-AHSA (SA)

(21) Appl. No.: 17/749,531

(22) Filed: May 20, 2022

(51) Int. Cl. H01G 11/86; H01G 11/26; H01G 11/36; C23C 14/16; C23C 14/02; C23C 14/34; C23C 16/26; C23C 16/50; C23C 28/00

(52) U.S. Cl. CPC H01G 11/86; H01G 11/26; H01G 11/36; C23C 14/165; C23C 14/021; C23C 14/3464; C23C 16/26; C23C 16/50; C23C 28/322; C23C 28/34; H01G 11/54

(57) ABSTRACT

A method of making a multi-walled carbon nanotubes (MWCNTs) electrode is a deposition-based method for growing MWCNTs on copper (Cu) foils to make binder-free electrodes for energy storage devices, such as those used in batteries and supercapacitors. A chromium layer is sputter coated on a copper foil substrate, and a nickel catalyst layer is sputter coated on the chromium layer, such that the chromium layer forms an electrically conductive barrier layer between the nickel catalyst layer and the copper foil substrate. The multi-walled carbon nanotubes are then formed on the copper foil substrate using plasma enhanced chemical vapor deposition.

### BACKGROUND

### 1. Field

The disclosure of the present patent application relates to the manufacture of electrodes, such as those used in supercapacitors, and particularly to a method of making electrodes through the growth of multi-walled carbon nanotubes (MWCNTs) on copper (Cu) foils.

### 2. Description of the Related Art

A supercapacitor is a high-capacity capacitor with a capacitance value much higher than other capacitors, but with lower voltage limits, bridging the gap between electrolytic capacitors and rechargeable batteries. Supercapacitors typically store 10 to 100 times more energy per unit volume or mass than electrolytic capacitors, can accept and deliver charge much faster than batteries, and tolerate many more charge and discharge cycles than rechargeable batteries.

Supercapacitors consist of two electrodes separated by an ion-permeable membrane (referred to as a “separator”), and an electrolyte ionically connecting both electrodes. When the electrodes are polarized by an applied voltage, ions in the electrolyte form electric double layers of opposite polarity to the electrode's polarity. For example, positively polarized electrodes will have a layer of negative ions at the electrode/electrolyte interface along with a charge-balancing layer of positive ions adsorbing onto the negative layer. The opposite is true for the negatively polarized electrode.

Supercapacitor electrodes are generally thin coatings applied and electrically connected to a conductive, metallic current collector. Electrodes for supercapacitors must have good conductivity, high temperature stability, long-term chemical stability (i.e., inertness), high corrosion resistance and high surface areas per unit volume and mass. The most commonly used electrode material for supercapacitors is carbon in various forms, such as activated carbon (AC), carbon fiber-cloth (AFC), carbide-derived carbon (CDC), carbon aerogel, graphite/graphene, graphene and carbon nanotubes (CNTs).

Carbon nanotubes are categorized as single-walled carbon nanotubes (SWCNTs) or multi-walled carbon nanotubes (MWCNTs). The latter have one or more outer tubes successively enveloping a SWCNT. SWCNTs have diameters ranging between 1 and 3 nm. MWNTs have thicker coaxial walls, separated by spacing (0.34 nm) that is close to graphene's interlayer distance. Nanotubes can grow vertically on the electrode's collector substrate, with typical lengths of about 20 to 100 μm. Carbon nanotubes can greatly improve capacitor performance due to their highly wettable surface area and high conductivity.

MWCNTs have mesopores that allow for easy access of ions at the electrode-electrolyte interface. As the pore size approaches the size of the ion solvation shell, the solvent molecules are partially stripped, resulting in larger ionic packing density and increased faradaic storage capability.

At present, carbon nanotubes are typically deposited on the metal electrode substrate as a paste. Such pastes include binders, which lead to increased high interface resistances in the final product due to the continued presence of the binder and poor mechanical/electrical contact between the carbon nanotubes and the metal collectors, leading to poor power performance of the capacitor. As an alternative to the usage of such binder-containing pastes, carbon nanotubes have been grown on metal substrates with co-deposition of a metal catalyst. However, the continuing presence of the catalyst has led to poor power performance of the capacitor. It would be desirable to be able to use deposition to grow the carbon nanotubes, thus avoiding the binder-related issues, but without the power issues found in current catalyst-grown nanotube electrodes. Thus, a method of making an electrode having multi-walled carbon nanotubes solving the aforementioned problems is desired.

### SUMMARY

The method of making an electrode having multi-walled carbon nanotubes is a deposition-based method for growing multi-walled carbon nanotubes (MWCNTs) on copper (Cu) foils to make binder-free electrodes for energy storage devices, such as those used in batteries and supercapacitors. A chromium layer is sputter coated on a copper foil substrate, and a nickel catalyst layer is sputter coated on the chromium layer, such that the chromium layer forms an electrically conductive barrier layer between the nickel catalyst layer and the copper foil substrate. After this step, Plasma Enhanced Chemical Vapor Deposition (PECVD) is performed to facilitate growth of MWCNTs on the copper foil substrate. At the end of the growth period, the MWCNTs can be cooled, preferably under a H₂ gas environment. The MWCNTs can be used as a binder-free electrode for the fabrication of supercapacitors.

These and other features of the present subject matter will become readily apparent upon further review of the following specification.

### DETAILED DESCRIPTION OF THE PREFERRED EMBODIMENTS

A method of making an electrode having multi-walled carbon nanotubes (alternatively referred to herein as an MWCNTs electrode) is a deposition-based method for growing multi-walled carbon nanotubes (MWCNTs) on copper (Cu) foils to make binder-free electrodes for energy storage devices, such as those used in batteries and supercapacitors. The method includes sputter coating a copper foil substrate with a layer of chromium, and sputter coating a nickel catalyst layer on the chromium layer, such that the chromium layer forms an electrically conductive barrier layer between the nickel catalyst layer and the copper foil substrate. After this step, Plasma Enhanced Chemical Vapor Deposition (PECVD) can be performed to facilitate growth of MWCNTs on the copper foil substrate. At the end of the growth period, the MWCNTs can be cooled, preferably under a H₂ gas environment. The incorporation of the chromium in the catalyst support prevents diffusion of the nickel catalyst into the underlying copper, and further promotes the formation of a high-density population of catalyst particles, resulting in high density MWCNT growth.

In experiments, commercial grade copper (Cu) foil with a thickness of ˜0.1 mm (purity: 99.9% Cu) was used. Prior to growth, the Cu foil was cleaned by washing with deionized (DI) water, immersing in 10% HCl solution for 2-3 minutes, rinsing in DI water and drying with flowing air. To grow the multi-walled carbon nanotubes (MWCNTs) on the Cu foil, the copper substrate was placed in a sputter coater system and ˜20-25 nm of nickel (Ni) catalyst layer was deposited on its surface. Additionally, a chromium (Cr) layer of ˜5-10 nm was deposited, forming an electrically conductive, thin barrier layer between the copper substrate and the Ni catalyst layer. Following the sputter coating, plasma enhanced chemical vapor deposition (PECVD) was performed for the growth of the MWCNTs. At the end of the growth period, the samples were slowly cooled within the furnace, under a hydrogen gas (H₂) environment. The MWCNTs grown on the Cu foil were characterized and used as binder-free electrodes for the fabrication of supercapacitors.

For material characterization, the structural properties of the samples were obtained using a Philips® X'Pert MPD X-ray diffraction system equipped with Cu Kα radiation in the 20 range of 10°-70°. The grown product was studied using field emission scanning electron microscopy (FESEM) with a JEOL® JSM-7600F Schottky field emission scanning electron microscope, and also transmission electron microscopy (TEM) with a JEOL® JEM-2100F field emission electron microscope operated at 200 kV. Room temperature Raman spectroscopy was carried out using a LabRAM® HR800 confocal Raman microscope in an ambient atmosphere with a He—Ne wavelength laser of 633 nm and power of 20 mW. The characterization revealed that the grown MWCNTs had a crystalline structure with diameters ranging from 10-15 nm and lengths of ˜10-12 μm.

Electrochemical measurements of the MWCNTs were performed using three electrode cells in an electrochemical analyzer system. For the working electrode, binder-free MWCNTs on a Cu substrate were used, prepared as described above. All electrochemical studies were carried out in electrolytes including KCl and other neutral electrolytes with a counter electrode of a Pt wire, and Ag/AgCl served for the reference electrode. Cyclic voltammetry (CV) studies and charge-discharge (CD) studies were conducted. A frequency ranging from 1 Hz to 100 kHz was used for an electrochemical impedance spectroscopy (EIS) analysis. The electrochemical studies showed that the MWCNTs electrodes demonstrated good electrochemical performance and cyclic stability for thousands of charge/discharge cycles. Electrochemical studies were also performed to study the effect of thickness of the Ni catalyst layer, with or without the Cr barrier layer.

It is to be understood that the method of making an electrode having MWCNTs electrode is not limited to the specific embodiments described above, but encompasses any and all embodiments within the scope of the generic language of the following claims enabled by the embodiments described herein, or otherwise shown in the drawings or described above in terms sufficient to enable one of ordinary skill in the art to make and use the claimed subject matter.

1. A method of making a MWCNTs electrode, consisting of the steps of:
sputter coating a chromium layer on a copper foil substrate;
sputter coating a nickel catalyst layer on the chromium layer, such that the chromium layer forms an electrically conductive barrier layer between the nickel catalyst layer and the copper foil substrate; and
using plasma enhanced chemical vapor deposition to form the MWCNTs electrode;
wherein the MWCNTs have diameters between 10-15 nm and lengths between 10-12 μm.

2. The method of making a MWCNTs electrode as recited in claim 1, wherein the chromium layer sputter coated on the copper foil substrate has a thickness between 5 nm and 10 nm.

3. The method of making a MWCNTs electrode as recited in claim 2, wherein the nickel catalyst layer sputter coated on the chromium layer has a thickness between 20 nm and 25 nm.

4. The method of making a MWCNTs electrode as recited in claim 1, further comprising the step of cooling the MWCNT electrode in a gaseous hydrogen atmosphere.

5. The method of making a MWCNTs electrode as recited in claim 1, wherein, prior to the step of sputter coating the chromium layer on the copper foil substrate, the copper foil substrate is cleaned with deionized water and hydrochloric acid.

6. A supercapacitor comprising the electrode of claim 1 as a working electrode.

7. The supercapacitor of claim 6, further comprising three electrode cells.

8. The supercapacitor of claim 6, further comprising a counter electrode comprising a Pt wire.

9. The supercapacitor of claim 6, further comprising a reference electrode comprising Ag/AgCl.

10. The supercapacitor of claim 6, further comprising an electrolyte comprising KCl and at least one other neutral electrolyte.

11. The supercapacitor of claim 6, wherein the MWCNTs electrode is configured to sustain at least one thousand charge/discharge cycles.
